(19) United States
(12) Patent Application Publication
(10) Pub. No.: US 2022/0138364 A1
(43) Pub. Date: May 5, 2022

(54) SYSTEMS AND METHODS FOR AUTOMATED INTERIOR FURNISHING BASED ON RESIDENT PROFILE

(71) Applicant: Ke.com (Beijing) Technology Co., Ltd., Beijing (CN)

(72) Inventors: Mingzhe TIAN, Beijing (CN); Cihui PAN, Beijing (CN); Yilang HU, Beijing (CN); Linyuan LI, Beijing (CN); Shen ZHANG, Beijing (CN)

(73) Assignee: Ke.com (Beijing) Technology Co., Ltd., Beijing (CN)

(21) Appl. No.: 17/489,777

(22) Filed: Sep. 30, 2021

(30) Foreign Application Priority Data
Oct. 30, 2020 (CN) 202011199734.9

(51) Int. Cl. G06F 30/13; G06F 9/451

(52) U.S. Cl. CPC G06F 30/13; G06F 9/451

(57) ABSTRACT

Systems and methods for generating a furnishing plan for a property are disclosed. An exemplary system includes a communication interface configured to receive a floor plan of the room and a resident profile. The system further includes at least one processor configured to determine a functionality of the room based at least partially on the resident profile and obtain a set of candidate furnishing items for the room based on the functionality of the room. The at least one processor is further configured to sequentially add furnishing items selected from the set of candidate furnishing items in the placement item set, where the furnishing items added in the furnishing plan collectively meet a predetermined area occupation threshold associated with the floor plan. The at least one processor is also configured to generating the furnishing plan based on the placement item set.

### CROSS-REFERENCE TO RELATED APPLICATIONS

This application hereby claims the benefits of priority to Chinese Application No. 202011199734.9 filed on Oct. 30, 2020, which is hereby incorporated by reference in its entirety.

### TECHNICAL FIELD

The present disclosure relates to systems and methods for automated interior furnishing, and more particularly, to systems and methods for providing interior furnishing recommendations based on resident profiles.

### BACKGROUND

Property owners may need assistance with interior design at various occasions, such as, when they would like to finish a new space, refurnish a space, or stage a space before putting the property on the market. One challenge with interior furnishing is to select proper furniture that is functional for the space as well as appealing to the occupant. For example, to furnish a child's bedroom, the property owner may select furnishing pieces according to the child's preference. However, the dimensions of the pieces may not collectively fit in the room. It is usually not clear to the property owner until the pieces of furniture are all purchased and placed into the room.

On the other hand, while certain automated systems can select furniture pieces that are adapt to the space, the selection may not reflect the needs and preferences of the occupant. For example, an automated system may select a twin bed, a dresser, and a nightstand for a child's bedroom. However, the child may prefer to have a double bed and a study desk in his bedroom instead.

### SUMMARY

Interior furnishing can greatly benefit from automatically selected furnishing pieces for an actual space that can both accommodate the user preferences and comply to the structural features of the space. To address these needs, embodiments of the disclosure provide automated systems and methods for providing furnishing recommendations based on resident profiles.

In one aspect, the disclosure provides a system for generating a furnishing plan for a property. An exemplary system includes a communication interface configured to receive a floor plan of the room and a resident profile. The system further includes at least one processor configured to determine a functionality of the room based at least partially on the resident profile and obtain a set of candidate furnishing items for the room based on the functionality of the room. The at least one processor is further configured to sequentially add furnishing items selected from the set of candidate furnishing items in the placement item set, where the furnishing items added in the furnishing plan collectively meet a predetermined area occupation threshold associated with the floor plan. The at least one processor is also configured to generating the furnishing plan based on the placement item set.

In another aspect, the disclosure further provides a method for generating a furnishing plan of a room. The method includes receiving, by a communication interface, a floor plan of the room and a resident profile. The method further includes determining, by at least one processor, a functionality of the room based at least partially on the resident profile and obtaining a set of candidate furnishing items for the room based on the functionality of the room. The method also includes sequentially adding, by the at least one processor, furnishing items selected from the set of candidate furnishing items to a placement item set. The furnishing items added in the placement item set collectively meet a predetermined area occupation threshold associated with the floor plan. The method additionally includes generating, by the at least one processor, the furnishing plan based on the placement item set.

In yet another aspect, the disclosure also provides a non-transitory computer-readable medium having stored thereon computer instructions, when executed by at least one processor, perform a method generating a furnishing plan of a room. The method includes receiving a floor plan of the room and a resident profile. The method further includes determining a functionality of the room based at least partially on the resident profile and obtaining a set of candidate furnishing items for the room based on the functionality of the room. The method also includes sequentially adding furnishing items selected from the set of candidate furnishing items to a placement item set. The furnishing items added in the placement item set collectively meet a predetermined area occupation threshold associated with the floor plan. The method additionally includes generating the furnishing plan based on the placement item set.

It is to be understood that both the foregoing general description and the following detailed description are exemplary and explanatory only and are not restrictive of the invention, as claimed.

### BRIEF DESCRIPTION OF THE DRAWINGS

FIG. 1 illustrates a schematic diagram of an exemplary three-dimensional view of a real state property, according to embodiments of the disclosure.

FIG. 2 is a block diagram of an exemplary interior furnishing device, according to embodiments of the disclosure.

FIG. 3 is a flowchart of an exemplary method for generating a furnishing plan for a room, according to embodiments of the disclosure.

FIGS. 4A-4C illustrate exemplary furnishing items selected for a living room based on occupant preferences, according to embodiments of the disclosure.

FIGS. 5A-5C illustrate exemplary furnishing plans generated for various rooms of different functionalities, according to embodiments of the disclosure.

FIG. 6 is a flowchart of an exemplary method for adjusting a furnishing plan for a room to meet placement criteria, according to embodiments of the disclosure.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

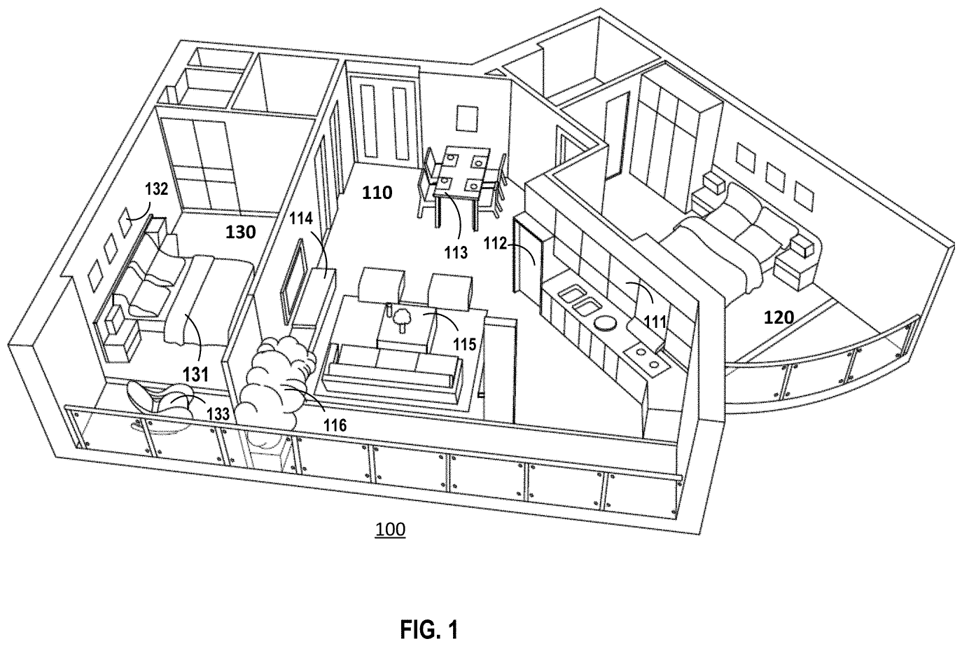

FIG. 1 illustrates a schematic diagram of an exemplary three-dimensional (3D) view of a real estate property 100 (hereafter “property 100”), according to embodiments of the disclosure. In some embodiments, property 100 may be a residential property such as a house, an apartment, a townhouse, a garage, or a commercial property such as a warehouse, an office building, a hotel, a museum, and a store, etc. In some embodiments, property 100 may include multiple rooms or functional spaces separated by interior walls. For example, property 100 may include a living room, bedroom, dining room, kitchen, bathroom, etc. As shown in FIG. 1, property 100 may include a great room 110 that has combined functions of a living room and a kitchen and bedrooms 120 and 130.

Consistent with embodiments of present disclosure, interior design of property 100 may include furnishing and decorating the room of the property. For example, as shown in FIG. 1, great room 110 may be furnished with dining table set 113, a TV stand 114, and a living room set 115. Great room 110 may be further decorated with, e.g., plants 116. Similarly, bedroom 130 may be furnished with a bed 131 and a rocking chair 133, and decorated with pictures 132. Sometimes, property owners may want to refurnish/redecorate the respective spaces, to accommodate different use or style. For example, bedroom 130 may be converted to a nursery in expectation of a newborn, so that bed 131 may be replaced with a crib and a changing table, and the room may be decorated with a cartoon theme. As another example, the property owner may have a change of taste and would like to replace European style furniture with modern furniture. Sometimes, properties may be staged with staging furniture and decorative pieces before conducting open houses.

Selecting property furniture for a room is usually time consuming and expensive. Property owners do not want to wait until the pieces of furniture are purchased and delivered to find that they do not fit into the room. It would be a hassle to return or change the furniture. The present disclosure provides artificial intelligence systems and methods for generating a furnishing plan for a space (e.g., a room of property 100) based on the resident profile (e.g., the family of residents living in property 100). Some embodiments of the disclosed systems and methods also provide a visualization of the same, so that the user (e.g., a property owner or an interior designer) could have a close-to-reality feel of the design effect in the space.

Consistent with some embodiments, a three-dimensional view of the rooms of property 100 may be rendered. As shown in FIG. 1, the three-dimensional view virtually recreates property 100 including its floor plan (e.g., the framing structures that divide the property into several rooms such as walls and counters) and furniture and decorations (e.g., beds, desks, tables and chairs, sofas, TV stands, bookshelves, wall paintings, mirrors, plants, etc.)

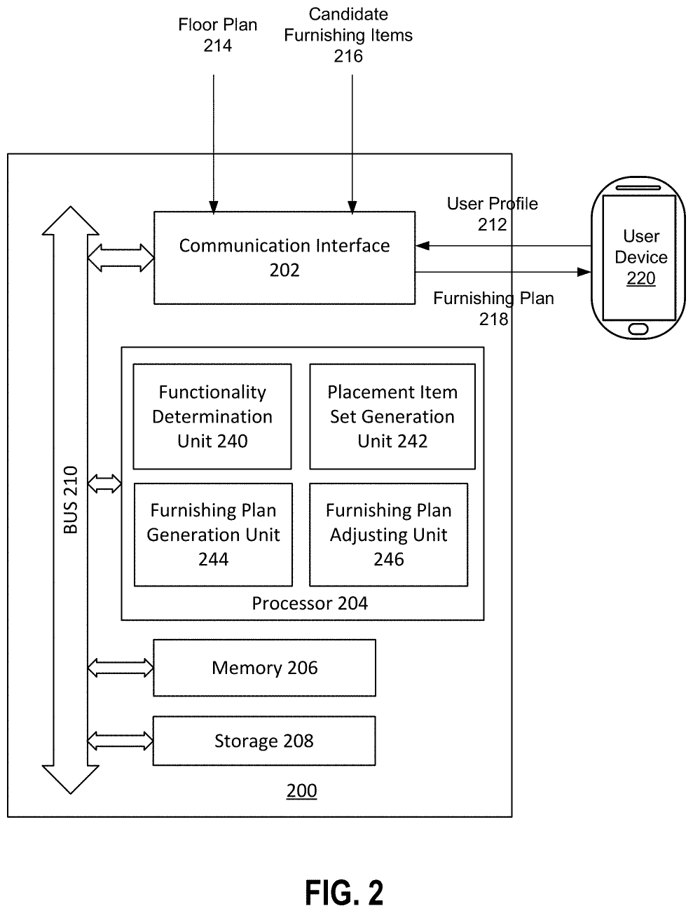

FIG. 2 is a block diagram of an exemplary interior design device 200, according to embodiments of the disclosure. In some embodiments, interior design device 200 may be implemented by a physical server or a service in the cloud. In some other embodiments, interior design device 200 may be implemented by a computer or a consumer electronic device such as a mobile phone, a pad, or a wearable device. As shown in FIG. 2, interior design device 200 may include a communication interface 202, a processor 204, a memory 206, a storage 208, and a bus 210. In some embodiments, interior design device 200 may have different modules in a single device, such as an integrated circuit (IC) chip (implemented as an application-specific integrated circuit (ASIC) or a field-programmable gate array (FPGA)), or separate devices with dedicated functions. Components of interior design device 200 may be in an integrated device, or distributed at different locations but communicate with each other through a network (not shown). The various components of interior design device 200 may be connected to and communicate with each other through bus 210.

Communication interface 202 may send data to and receive data from components such as user device 220 via direct communication links, a Wireless Local Area Network (WLAN), a Wide Area Network (WAN), wireless communication networks using radio waves, a cellular network, and/or a local wireless network (e.g., Bluetooth™ or WiFi), or other communication methods. In some embodiments, communication interface 202 can be an integrated services digital network (ISDN) card, cable modem, satellite modem, or a modem to provide a data communication connection. As another example, communication interface 202 can be a local area network (LAN) card to provide a data communication connection to a compatible LAN. Wireless links can also be implemented by communication interface 202. In such an implementation, communication interface 202 can send and receive electrical, electromagnetic or optical signals that carry digital data streams representing various types of information via a network.

Consistent with some embodiments, communication interface 202 may receive resident profile 212, e.g., from user device 220. In some embodiments, user device 220 may be a cellular device or a smart phone, a personal digital assistant (PDA), a laptop computer, a tablet device and a wearable device, which may provide network connection and process resources to communicate with interior design device 200 through communication interface 202. User device 220 may also include, for example, an on-board computing system or customized hardware. User device 220 may also run designated service applications such as interior design applications to provide design assistance and suggestions to the user. User device 220 may include an interface for user interaction. For example, the interface may be a touchscreen or a keyboard (physical keyboard or soft keyboard) for the user to input data to user device 220. In some embodiments of the present disclosure, user may send resident profile 212 to interior design device 200, via user device 220.

In some embodiments, communication interface 202 may further receive floor plan 214 of a room to the furnished and candidate furnishing items 216 that can be selected from for furnishing the room. Communication interface 202 may provide the received information or data to memory 206 and/or storage 208 for storage or to processor 204 for processing. In some embodiments of the present disclosure, interior design device 200 may provide design suggestions (e.g., furnishing plans) and visual representations to user device 220 through communication interface 202. User device 220 may display the suggestions and representations to the user through the interface. For example, user device 220 may display a rendered view of the furnishing plan with suggested furnishing items inserted in the floor plan of the room.

Processor 204 may include any appropriate type of general-purpose or special-purpose microprocessor, digital signal processor, or microcontroller. Processor 204 may be configured as a separate processor module dedicated to interior design. Alternatively, processor 204 may be configured as a shared processor module for performing other functions related to or unrelated to interior design. For example, the interior design application is just one application installed on a versatile device.

As shown in FIG. 2, processor 204 may include multiple modules, such as a functionality determination unit 240, a placement item set generation unit 242, a furnishing plan generation unit 244, a furnishing plan adjusting unit 246, and the like. These modules (and any corresponding sub-modules or sub-units) can be hardware units (e.g., portions of an integrated circuit) of processor 204 designed for use with other components or to execute part of a program. The program may be stored on a computer-readable medium (e.g., memory 206 and/or storage 208), and when executed by processor 204, it may perform one or more functions. Although FIG. 2 shows units 240-246 all within one processor 204, it is contemplated that these units may be distributed among multiple processors located near or remotely with each other.

Memory 206 and storage 208 may include any appropriate type of mass storage provided to store any type of information that processor 204 may need to operate. Memory 206 and storage 208 may be a volatile or non-volatile, magnetic, semiconductor, tape, optical, removable, non-removable, or other type of storage device or tangible (i.e., non-transitory) computer-readable medium including, but not limited to, a ROM, a flash memory, a dynamic RAM, and a static RAM. Memory 206 and/or storage 208 may be configured to store one or more computer programs that may be executed by processor 204 to perform image processing, interior design suggestion, and view rendering as disclosed herein. For example, memory 206 and/or storage 208 may be configured to store program(s) that may be executed by processor 204 to recommend furniture pieces for an interior space based on a resident profile of the residents occupying that space, and then render a view that shows the recommended pieces in the actual space.

Memory 206 and/or storage 208 may be further configured to store information and data used by processor 204. For instance, memory 206 and/or storage 208 may be configured to store various data received by interior design device 200, such as resident profile 212, floor plan 214, and candidate furnishing items 216. Memory 206 and/or storage 208 may also be configured to store intermediate data generated by processor 204, such as attributes of furnishing items, placement item set with a list of furnishing items selected for a space, various furniture placement criteria, a furnishing plan generated for the space, and views rendered to visualize the furnished/refurnished space. The various types of data may be stored permanently, removed periodically, or disregarded immediately after it is processed.

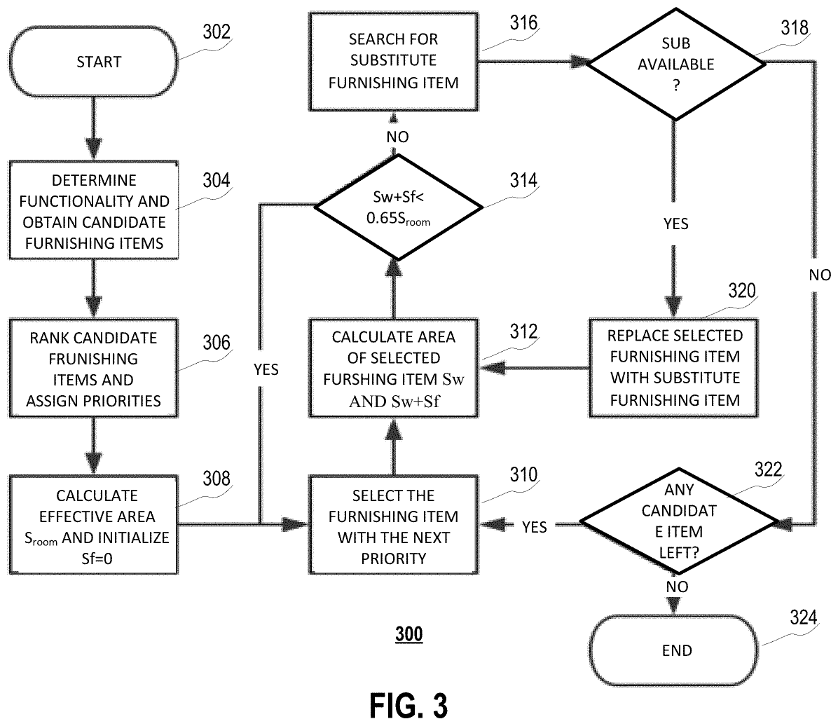

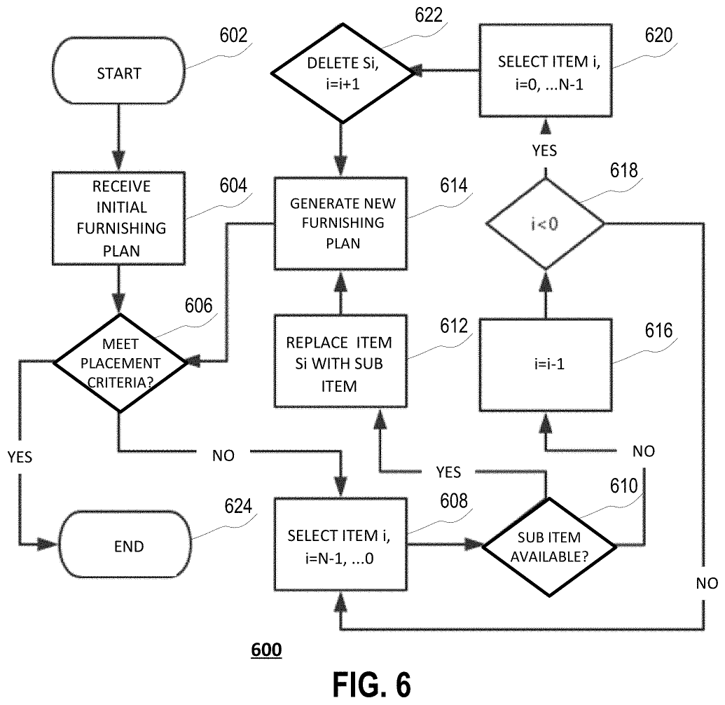

Interior design device 200, alone or along with user device 220, may be configured to perform methods for generating furnishing plans and adjusting the furnishing plans in light of the placement criteria, such as those shown by flowcharts of FIGS. 3 and 6.

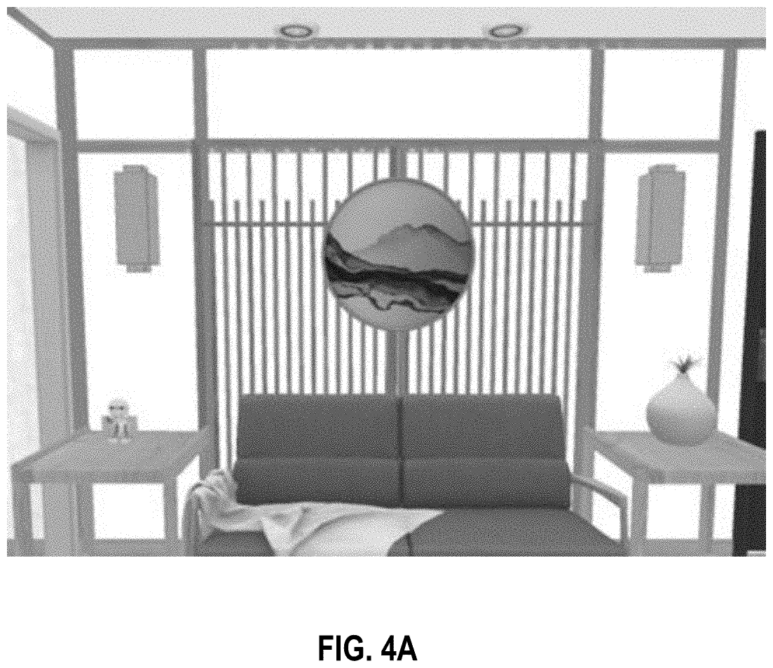

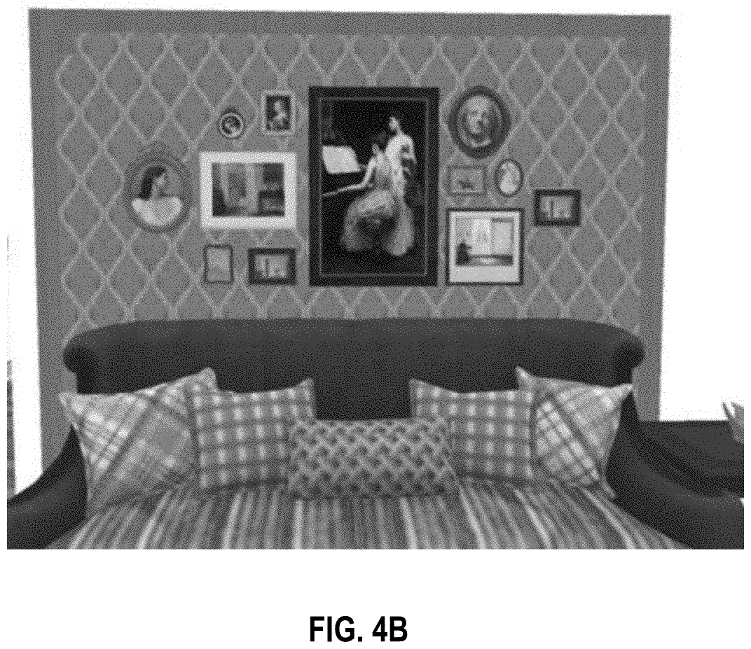

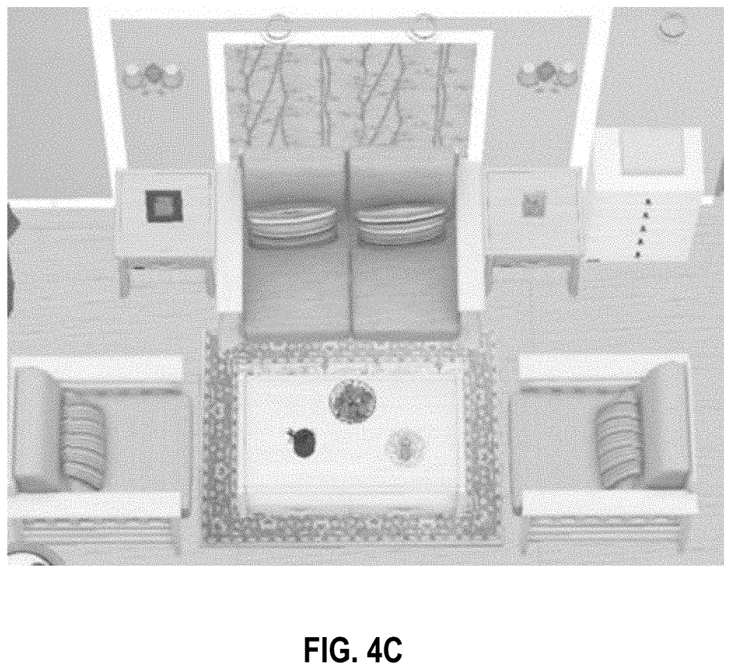

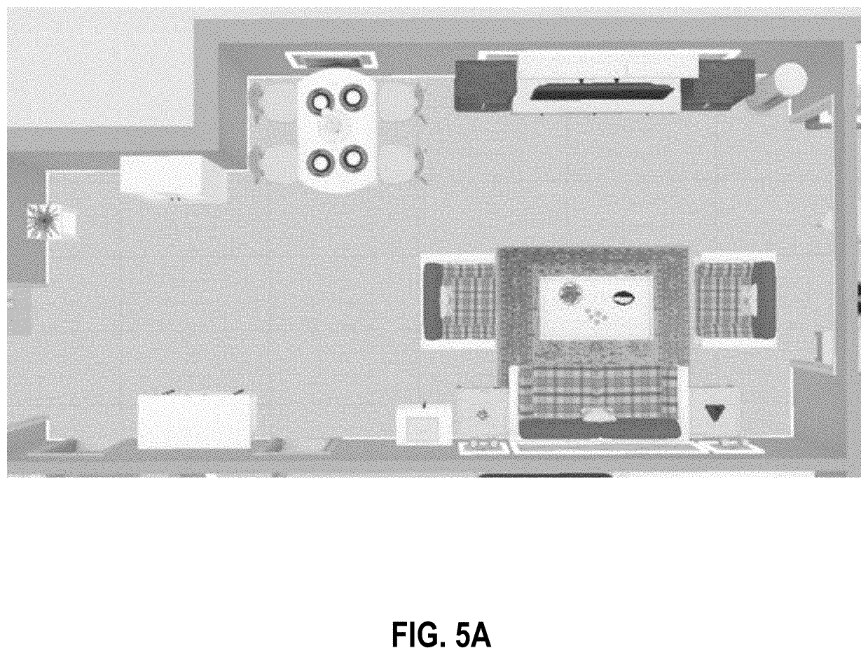

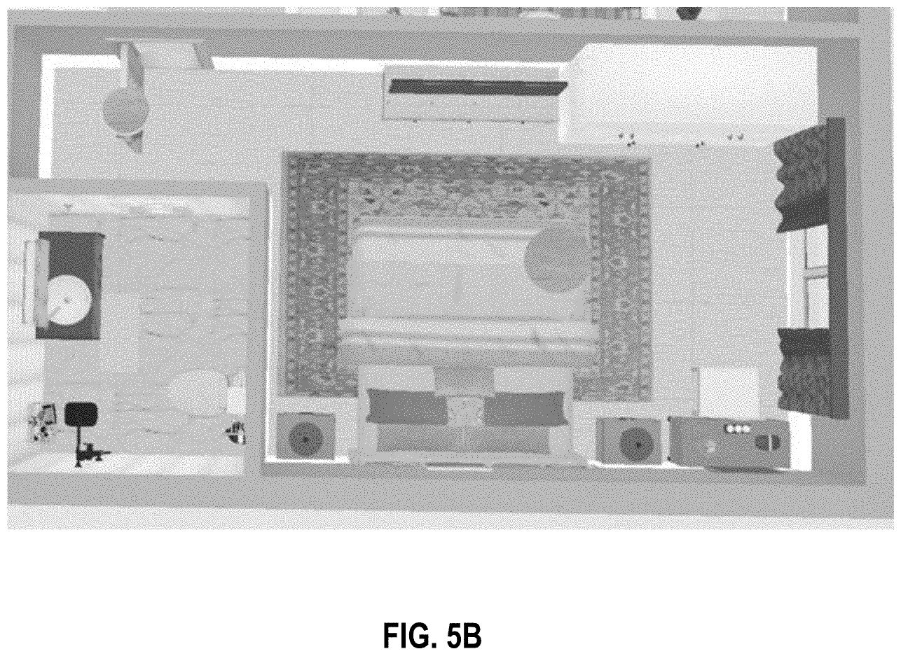

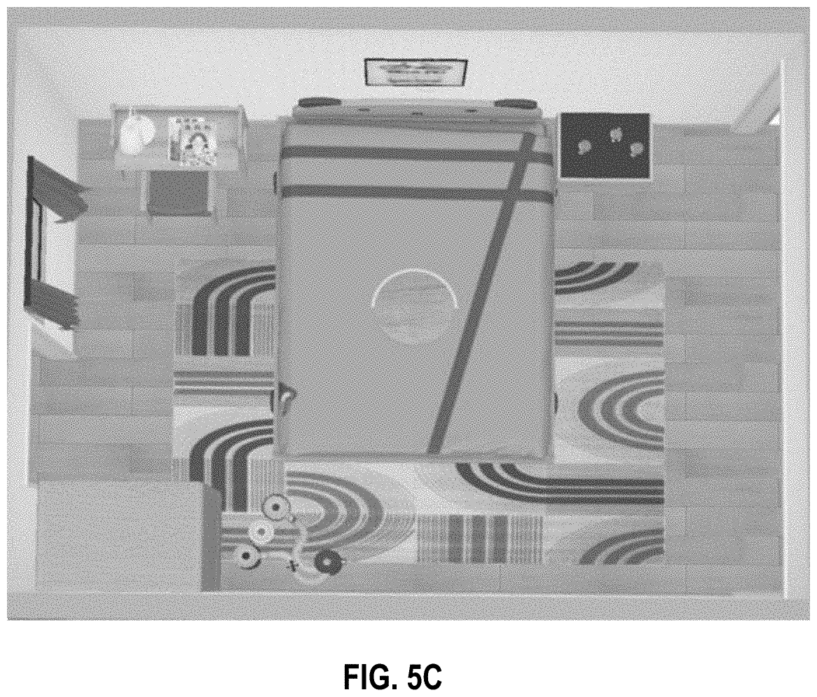

FIG. 3 is a flowchart of an exemplary method 300 for generating a furnishing plan for a room, according to embodiments of the disclosure. In some embodiments, method 300 may be performed by processor 204 of interior design device 200. Method 300 may include steps 302-324 as described below. It is to be appreciated that some of the steps may be optional to perform the disclosure provided herein. Further, some of the steps may be performed simultaneously, or in a different order than shown in FIG. 3. For description purposes, method 300 will be described as to generate furnishing plans for furnishing the spaces as shown in FIGS. 4A-4C and FIGS. 5A-5C. Method 300, however, can be implemented for furnishing other spaces of a property.

Method 300 starts at Step 302 where interior design device 200 may receive resident profile 212 (e.g., from user device 220), and floor plan 214 of the room to be furnished. In some embodiments, resident profile 212 includes information of residents/occupant(s) of the room, such as family members who live in the property, their respective attributes, such as gender, age, hobbies, habits, and style preferences. For example, Table 1 shows the resident profile of an exemplary family:

TABLE 1

| | | | | | | | |
|---|---|---|---|---|---|---|---|
| Name | Age | Gende | Hobby1 | Hobby2 | Hobby3 | Hobby4 | Style |

| | | | | | |
|---|---|---|---|---|---|
| Father | Middle | Male | Sports | Pets_cat | Italian |
| Mother | Middle | Female | Music | | Italian |
| Baby | Baby | Male | | | |
| Kid | Children | Female | Toys | Painting | |

In some embodiments, floor plan 214 defines the layout of the room, including its boundaries (e.g., surrounding walls) and their dimensions, locations and sizes of openings (e.g., door, window, closet, etc.), and clearances associated with the openings. In some embodiments, the room may be regular-shaped, such as square or rectangular, with four sides as boundaries. In some other embodiments, the room may be irregular-shaped, e.g., with carve-out or extension on a side or in a corner.

In step 304, functionality determination unit 240 of interior design device 200 determines the functionality of the room and obtains furnishing items corresponding to the functionality of the room. Functionality of a room indicates the function of the room when used by its occupant(s). For example, the functionality may include, but not limited to, bedroom, living room, kitchen, study/office, gym, musical studio, and painting studio, etc. Some rooms may have dual or multiple functionalities, e.g., a bedroom and study.

In some embodiments, functionality of the room may be determined based on resident profile 212. For example, based on the resident information indicated by resident profile 212, functionality determination unit 240 determines whether the room has to be a bedroom, or it can be furnished as a non-bedroom. In order to make that determination, functionality determination unit 240 may first determine the minimum number of bedrooms needed by the family indicated by resident profile 212 and compare that minimum number with the actual number of bedrooms currently in the property.

In some embodiments, as described above and exemplified in Table 1, the resident information indicated by resident profile 212 may include demographic information (e.g., the number and composition of family members in the family), and attributes of each family member (e.g., gender, age, hobbies, living habits, and style preference, etc.) Based on the resident information, the minimum number of bedrooms needed by the family can be determined by first calculating N_{bedroom} using formula (1) below:

N_{bedroom}=(N_{midage}+1)//2+(N_{kids}+1)//2+(Nₛₑₙᵢₒᵣ+1)//2+(Nₒₜₕₑᵣ+1)//2 (1)

where N_{kids} is the number of kids in the family, N_{midage} is the number of middle-aged adults in the family (e.g., parents of the kids), Nₛₑₙᵢₒᵣ is the number of seniors in the family (e.g., grandparents of the kids), and Nₒₜₕₑᵣ is the number of other people in the family (e.g., relatives and friends of the family). In formula (1), the operator//works as a floor division for integer arguments, and it returns the closest integer value which is less than or equal to the specified expression or value.

Formula (1) assumes that two married adults (middle-aged adults or seniors or other) as well as two sibling kids will share a bedroom, and a single adult or a single kid will have his or her own room. In formula (1), kids are not made to share bedrooms with adults. However, sometimes, the number of bedrooms available in the property may be less than the calculated N_{bedroom}, in which case, the minimum number of bedrooms needed by the family can be alternatively determined by calculating N_{bedroom_min1} and N_{bedroom_min2} using one of the following formulas (2) and (3), respectively:

N_{bedroom_min1}=(N_{midage}+N_{kids}+1)//2+(Nₛₑₙᵢₒᵣ+1)//2+(Nₒₜₕₑᵣ+1)//2 (2)

N_{bedroom_min2}=(Nₛₑₙᵢₒᵣ+N_{kids}+1)//2+(N_{midage}+1)//2+(Nₒₜₕₑᵣ+1)//2 (3)

where N_{kids} is the number of kids in the family, N_{midage} is the number of middle-aged adults in the family (e.g., parents of the kids), Nₛₑₙᵢₒᵣ is the number of seniors in the family (e.g., grandparents of the kids), and Nₒₜₕₑᵣ is the number of other people in the family (e.g., relatives and friends of the family). Formulas (2) and (3) assume that kids will share a bedroom with adults (middle-aged adults or seniors) in order to reduce the number of bedrooms needed.

The minimum number of bedrooms needed by the family can be then determined as the smaller of N_{bedroom_min1} or N_{bedroom_min2}, i.e., Min(N_{bedroom_min1}, N_{bedroom_min2}). Interior design device 200 then compares the minimum number of bedrooms needed by the family with the number of existing bedrooms in the property. If the minimum number of bedrooms needed by the family is equal to or more than the number of existing bedrooms in the property, all the rooms have to be designated as bedrooms and none can be used for other functionalities. Accordingly, interior design device 200 will determine the functionality of the current room as a bedroom.

If the minimum number of bedrooms needed by the family is less than the number of existing bedrooms in the property, there is already sufficient number of bedrooms and thus certain rooms can be designated as non-bedroom for some other functionalities. In some embodiments, functionality determination unit 240 can rank all the rooms in the property based on certain criteria, such as according to the size of each room (e.g., a higher rank for a room with a larger size). Based on the ranking, functionality determination unit 240 may select the first T rooms (T being the minimum number of bedrooms needed by the family) with highest ranks as bedrooms, and designate the rest as can be used for other functionalities.

When it is determined that the current room can indeed be used as a non-bedroom, functionality determination unit 240 may determine its functionality based on predetermined criteria, e.g., in the order of study—gym—music studio—painting studio, etc. For example, functionality determination unit 240 may first check whether there is already a room designated as study in the property, and if not, the functionality of the current room will be designated as a study. If there is already a study in the property, functionality determination unit 240 may move down the list in the predetermined order, and check if there is a gym in the property. If no existing gym, the functionality of the current room will be designated as a gym and if there is an existing gym in the property, functionality determination unit 240 may move further down the list and check if there is a music studio in the property, and so on.

After determining the functionality of the room and as part of step 304, interior design device 200 obtains candidate furnishing items 216 that correspond to the functionality. Candidate furnishing items 216 are items that can be used to furnish the room. Furnishing items may be later selected from candidate furnishing items 216 to form the placement item set. In some embodiments, candidate furnishing items 216 may include requisite items that are required by the functionality of the room. For example, when the functionality of the room is a bedroom, candidate furnishing items 216 may include a bed, a dresser, and a vanity, etc. As another example, when the functionality of the room is a living room, candidate furnishing items 216 may include a sofa, a TV standard, and a coffee table, etc. In some embodiments, candidate furnishing items 216 may include appended/complementary items of the requisite items. For example, when a bed is a requisite item included in candidate furnishing items 216, one or more nightstands may be included in candidate furnishing items 216 as appended/complementary items. As another example, when a sofa is a requisite item included in candidate furnishing items 216, one or more side tables may be included in candidate furnishing items 216 as appended/complementary items to the sofa. In some embodiments, candidate furnishing items 216 may be saved in a database and each associated with one or more functionalities of room.

In some embodiments, as part of Step 304, interior design device 200 may obtain candidate furnishing items 216 further based on the occupant of the room. In particular, when the functionality is determined to be a bedroom, the associated furnishing items available in the database may include beds of different sizes (e.g., king size, queen size, double, twin or bunk bed) and their appended/complementary nightstands suitable for different occupant scenarios. For example, Table 2 lists exemplary furnishing items corresponding to a bedroom functionality.

TABLE 2

| Category | Width | Length | AllowW | AllowL | AddLmt | Substitute | Priority | Class | Append |
|---|---|---|---|---|---|---|---|---|---|
| bed1_beside1 | 1.8 | 2.2 | 0.2 | 0.4 | 10 | bed1 | High | bed | beside_table |
| bed1 | 1.2 | 2.1 | 0.2 | 0.4 | 10 | children_bed | High | bed | |
| bed2_beside2 | 3.2 | 2.2 | 0.2 | 0.4 | 10 | bed2_beside1 | High | bed | beside_table |
| bed2_beside1 | 2.65 | 2.2 | 0.2 | 0.4 | 10 | bed2 | High | bed | beside_table |
| bed2 | 2.1 | 2.2 | 0.2 | 0.4 | 10 | | High | bed | |
| tatami_big | 2.8 | 1.5 | 0 | 0.4 | 5 | tatami_small | High | bed | |
| tatami_small | 2.2 | 1 | 0 | 0.4 | 5 | | High | bed | |
| cot | 1.2 | 0.8 | 0.2 | 0.2 | 5 | | High | bed | |
| children_bed | 1.3 | 2 | 0.2 | 0.4 | 5 | | High | bed | |
| children_bed_beside1 | 1.85 | 2 | 0.2 | 0.4 | 5 | children_bed | High | bed | beside_table |
| children_bed_beside2 | 2.4 | 2 | 0.2 | 0.4 | 5 | children_bed | High | bed | beside_table |
| children_bed2 | 1.2 | 2 | 0.2 | 0.4 | 5 | children_bed | High | bed | |
| children_bedHL | 1.6 | 2.2 | 0.2 | 0.4 | 5 | | High | bed | |

As shown in Table 2, six types of beds are available, including adult beds bed 1, bed 2, children's beds children_bed and children_bed2, and Japanese style tatamis tatami_big and tatami_small. The beds also have their appended/complementary nightstands (referred to as “beside tables” in Table 2). Table 2 also lists the dimensions, including the allowance dimensions for each furnishing item, substitute items of some furnishing items, as well as priority and class of each furnishing item. For a particular bedroom, not all the bed items are relevant, and therefore, interior design device 200 may not include all of them in candidate furnishing items 216.

In some embodiments, interior design device 200 may further determine the occupant of the room and select the relevant candidate furnishing items 216 based on the occupant. For example, interior design device 200 may assign the family members to the available bedrooms in the property as occupant(s). In some embodiments, the bedrooms may be ranked according to their priorities. In some embodiments, the priorities of the bedrooms can be determined based on their adjacent/attached rooms, such as shown in Table 3.

TABLE 3

Adjacent room

| Room | bathroom | clothing closet | other |
|---|---|---|---|
| Bedroom | max(p, 2) | max(p, 1) | max(p, 0) |

As shown in Table 3, a bedroom with its adjacent room being a bathroom is assigned a priority of 2, a bedroom with its adjacent room being a clothing closet is assigned a priority of 1, and a bedroom with an adjacent room of another type is assigned a priority of 0. That is, a bedroom adjacent a bathroom has a higher priority than a bedroom adjacent a clothing closet. Based on the priorities of the bedrooms, interior design device 200 then assigns the bedrooms to the family members in a predetermined order. For example, where there are 2 bedrooms in the property and the family includes parents and their child, interior design device 200 may assign the bedroom with the higher priority to the parents and the other bedroom to the child.

Based on the occupant(s) of the room, interior design device 200 may select candidate furnishing items 216 from available furnishing items that suit the occupant(s)' needs. In some embodiments, the items may be selected based on the age of the occupant. For example, if a bedroom is occupied by a child, candidate furnishing items 216 may include child beds or twin beds, and child desks and chairs, etc. If the bedroom is occupied by the parents, candidate furnishing items 216 may include double beds, queen beds, or king beds, and adult height desks and chairs, etc. In some embodiments, the items may be selected based on the gender of the occupant. For example, if a child bedroom is occupied by a girl, candidate furnishing items 216 in white or pink colors may be selected, while if it is occupied by a boy, items in black, brown, or blue colors may be selected.

In some further embodiments, interior design device 200 may further select the relevant candidate furnishing items 216 based on the occupant's preference. Each family member's preference may be indicated by resident profile 212. For example, FIGS. 4A-4C illustrate exemplary furnishing items selected for a living room based on occupant preferences, according to embodiments of the disclosure. If an occupant prefers a Japanese furnishing style, candidate furnishing items 216 may include items such as a futon sofa, side tables, lantern style lamps, a screen, etc., as shown in FIG. 4A. If an occupant prefers an Italian furnishing style, candidate furnishing items 216 may include European style items as shown in FIG. 4B. If an occupant prefers a country style, candidate furnishing items 216 may include items such as rattan sofa and chairs, bamboo coffee table and side tables, etc. as shown in FIG. 4C.

In Step 306, interior design device 200 ranks candidate furnishing items 216 and assigns priorities to the furnishing items obtained according to the functionality of the room. In some embodiments, the relative priorities of the requisite items may be predetermined. For example, candidate furnishing items 216 may include requisite items bed 1, dresser 1, and vanity 1, and the predetermined priorities are bed 1>dresser 1>vanity 1. The priorities of other items among candidate furnishing items 216 may be determined by interior design device 200 based on predetermined rules. These rules may include: (1) each requisite item has a higher priority than that of any appended/complementary item, and (2) an appended/complementary item has a higher priority if the associated requisite item has a higher priority. In the example above, if bed 1 has an appended/complementary item nightstand 1, and vanity 1 has an appended/complementary item vanity chair 1, based on these rules, interior design device 200 may rank candidate furnishing items 216 as follows: bed 1>dresser 1>vanity 1>nightstand 1>vanity chair 1. When placement items are selected from candidate furnishing items 216, items with higher priorities will be used to fit into the room first. In some embodiments, the furnishing items may be grouped in classes, and several alternative furnishing items may be available under each class. For example, as shown in Table 2, multiple different types of beds are available under the class “bed.” In that case, interior design device 200 may assign class-level priorities to the different class, and within each class, assign item-level priorities to the different furnishing items available under that class. In selecting the placement items, class-level priorities may be considered first and then the item-level priorities within the classes.

After candidate furnishing items 216 are determined and ranked, placement item set generation unit 242 of interior design device 200 starts to generate a placement item set with candidate items selected from candidate furnishing items 216. In some embodiments, placement item set has to satisfy the predetermined threshold on an area occupation ratio between the total area occupied by the furnishing items in the placement item set and the effective area of the room, as shown in formula (4) below:

Σᵢ₌₁ⁿSi<=Sroom×R (4)

where Sᵢ is the area occupied by a furnishing item i in the placement item set, Sᵣₒₒₘ is the effective area of the room, and R is the area occupation ratio threshold. Accordingly, the product between Sᵣₒₒₘ and R can be referred to as the area occupation threshold. In other words, the total area occupied by the furnishing items in the placement item set should not exceed the area occupation threshold.

In some embodiments, effective area Sᵣₒₒₘ may be the total area of the room excluding the opening areas, e.g., the door area and pass leading to other spaces. No furniture can be placed in the opening areas and thus these areas are excluded from the effective area. For example, a door area is the square area covered by opening of the door (width of the door being the side length of the square). A pass area is the rectangular area with the pass length as one side and 500 mm as the other side.

In some embodiments, the area occupation ratio threshold R may be determined based on one or more factors, such as the functionality of the room, preference of the occupant, etc. In some embodiments, the threshold may be determined statistically based on ample furnished samples rooms. For example, the area occupation ratio threshold may be set as 0.65. In other examples, the area occupation ratio threshold may be set as other suitable values, such as a number within the range of 0.5-0.75, etc.

In Step 308, interior design device 200 calculates the effective area Sᵣₒₒₘ and initialize S_{f}, where S_{f} is the total area occupied by the items in the placement item set, i.e., Sf=Σᵢ₌₁ⁿ Si. For example, S_{f} may be initialized to be 0 if there is no furnishing item in the room at all. Otherwise, S_{f} may be initialized to be the total area occupied by any existing furnishing item in the room. Placement item set generation unit 242 of interior design device 200 then performs steps 310-322 in loops to generate the placement item set. In some embodiments, placement item set generation unit 242 traverses candidate furnishing items 216 in the order of priority as determined in step 306, and sequentially adds the candidate furnishing items into the placement item set. During the placement item set generation process, the area occupation ratio is monitored and kept under the predetermined threshold.

In Step 310, placement item set generation unit 242 selects the furnishing item from candidate furnishing items 216 with the next highest priority. In Step 312, placement item set generation unit 242 calculates the area occupied by the selected furnishing item S_{w} and add it to the total area S_{f}, to determine a total area S_{w}+S_{f}. In some embodiments, S_{w} can be calculated based on the dimensions of the item and its allowance dimensions, e.g., as provided by Table 3.

In Step 314, placement item set generation unit 242 determines whether the total area S_{w}+S_{f} exceeds the effective area Sᵣₒₒₘ multiplied by the area occupation ratio threshold, e.g., 0.65 Sᵣₒₒₘ. If S_{w}+S_{f}<0.65 Sᵣₒₒₘ (Step 314: Yes), placement item set generation unit 242 will add the selected furnishing item to the placement item set and update S_{f} with S_{w}+S_{f} to account for the total area occupied by the placement item set with the added furnishing item. Placement item set generation unit 242 then proceeds to Step 310 where the furnishing item with the next priority will be selected. If S_{w}+S_{f}>=0.65 Sᵣₒₒₘ (Step 314: No), placement item set generation unit 242 will not add the selected furnishing item to the placement item set or update the total area S_{f} to include S_{w}. Instead, in Step 316, placement item set generation unit 242 searches for a substitute furnishing item of the selected furnishing item from candidate furnishing items 216.

If a substitute furnishing item is available (Step 318: YES), in Step 320, placement item set generation unit 242 replaces the selected furnishing item with the substitute furnishing item. Consistent with the present disclosure, a substitute furnishing item is of a same furniture type as the furnishing item but occupies a smaller area than the next furnishing item. For example, as shown in Table 2, nightstand bed2_beside1 is a substitute item of nightstand bed2_beside1, and bed children_bed is a substitute item for bed 1.

Placement item set generation unit 242 then proceeds to Step 312 and performs Steps 312-314 as described above with respect to the substitute furnishing item. If the substitute furnishing item could satisfy S_{w}+S_{f}<0.65 Sᵣₒₒₘ (Step 314: Yes), placement item set generation unit 242 will add the candidate furnishing item to the placement item set and update S_{f} with S_{w}+S_{f} to account for the total area occupied by the placement item set with the added furnishing item. Otherwise, if a substitute furnishing item is not available for the selected furnishing item (Step 318: NO), placement item set generation unit 242 will not add the selected furnishing item to the placement item list and proceed directly to Step 322 to confirm whether any candidate furnishing item is still left unconsidered.

If there is still a candidate furnishing item 216 left (Step 322: Yes), placement item set generation unit 242 proceeds to Step 310 where the furnishing item with the next priority will be selected. Otherwise, if all candidate furnishing items 216 are considered (Step 322: NO), method 300 may end in Step 324.

After placement item set generation unit 242 generates the placement item set, furnishing plan generation unit 244 may determine whether to recommend the placement item set to a user and if so, generate a furnishing plan 218 for placing the items of the placement item set in the room and provide the plan to user device 220 as a furnishing recommendation. In some embodiments, furnishing plan generation unit 244 may use Artificial Intelligence (AI) methods, such as deep learning methods, to determine an optimal placement of the furnishing items of the placement item set in the room, and calculate a matching score for the placement. The matching score indicates how much the furnishing items, when placed in the room according to the furnishing plan, match the floor plan of the room. If the matching score exceeds a predetermined threshold, furnishing plan generation unit 244 may decide to recommend the placement item set and provide furnishing plan 218 to user device 220. In some embodiments, to make the recommendation, furnishing plan generation unit 244 may render a 2D or a 3D view of the room with the items inserted in the floor plan of the room and send the view to user device 220 for display. AI techniques may be used to vender the view, and the visualization of the furnished room may be closer to reality. For example, the rendered review may be a 3D view of the room with the furnishing items, similar to rooms shown in FIG. 1.

For example, FIGS. 5A-5C illustrate exemplary furnishing plans generated for various rooms of different functionalities, according to embodiments of the disclosure. FIG. 5A is a rendered view of a furnished living room with furnishing items such as a sofa set with coffee table and side tables, a tv stand, and a dining room set, etc. FIG. 5B is a rendered view of a furnished bedroom with a walk-in bathroom attached to it. Furnishing items in the bedroom include such as a bed with two nightstands, a tv stand, a vanity and a vanity chair, etc. FIG. 5C is a rendered view of another furnished bedroom with a walk-in bathroom attached to it. Furnishing items in the bedroom include such as a bed with two nightstands, a tv stand, a vanity and a vanity chair, etc.

FIG. 6 is a flowchart of an exemplary method for adjusting a furnishing plan for a room to meet placement criteria, according to embodiments of the disclosure. In some embodiments, method 600 may be performed by processor 204 of interior design device 200, e.g., furnishing plan adjusting unit 246. Method 600 may include Steps 602-624 as described below. It is to be appreciated that some of the steps may be optional to perform the disclosure provided herein. Further, some of the steps may be performed simultaneously, or in a different order than shown in FIG. 6.

Method 600 starts at Step 602. In Step 604, interior design device 200 may receive an initial furnishing plan. For example, the initial furnishing plan may be furnishing plan 218 generated by performing method 600. In Step 606, furnishing plan generation unit 244 of interior design device 200 may determine whether the initial furnishing plan meets one or more predetermined placement criteria. In some embodiments, the placement criteria may be that the matching score calculated based on the placement item set in the initial furnishing plan has to exceed a predetermined threshold. If the matching score exceeds a predetermined threshold, furnishing plan generation unit 244 may decide the furnishing plan meets the placement criteria (Step 606: YES) and method 600 ends at Step 624. It is contemplated that other placement criteria may also be used.

If furnishing plan generation unit 244 decides the furnishing plan fails to meet the placement criteria (Step 606: NO), method 600 proceeds to Step 608 to adjust the furnishing plan. Furnishing plan adjusting unit 246 may traverse furnishing items in the placement item set of the furnishing plan in a reverse order and perform Steps 608-622 in loops. For example, if the placement item set of the furnishing plan has N items, item 0 to item N−1, furnishing plan adjusting unit 246 traverses the set in a reverse order from the (N−1)^{t} item to the 0^{th} item. Because the N items were added to the placement item set according to their priorities (i.e., items 0 to N−1 have descending priorities), by traversing the set in a reverse order, placement items with lower priorities are considered for substitution first. Accordingly, the placement items with higher priorities are more likely preserved.

In Step 608, furnishing plan adjusting unit 246 selects a furnishing item i and in Step 610 determines whether a substitute item is available for furnishing item i. For example, as shown in Table 2, nightstand bed2_beside1 is a substitute item of nightstand bed2_beside1, and bed children_bed is a substitute item for bed 1. If a substitute item is available (Step 610: YES), method 600 proceeds to Step 612 to replace furnishing item Si with its substitute item. Otherwise, if a substitute item is not available (Step 610: NO), method 600 returns to Step 608 to select the next furnishing item. Because the next furnishing item is the one before the current item in the placement item set, furnishing plan adjusting unit 246 reduces i by 1, i.e., i=i−1, in Step 616. If the reduced i<0 (Step 618: YES), that means the current furnishing item is already the first item in the placement item set, and furnishing plan adjusting unit 246 will restore i by making i=i+1 and delete item i in Step 622. Otherwise (Step 618: NO), method 600 returns to Step 608 to select the next furnishing item.

After either Step 612 (the current furnishing item Si being replaced by its substitute item) or Step 622 (the current furnishing item Si being deleted), method 600 proceeds to Step 614 where furnishing plan adjusting unit 246 generates a new furnishing plan based on the adjustment (e.g., substitution or deletion). The adjusted furnishing plan is then subject to the same determination of Step 606 to decide whether it meets the placement criteria. If after adjusting any item Si, the adjusted furnishing plan meets the placement criteria (Step 606: YES), method 600 can conclude in Step 624 and the adjusted furnishing plan may be provided to user device 220. If, after traversing the entire placement item set and making item adjustments, the adjusted furnishing plan still does not meet the placement criteria (Step 606: NO), interior design device 200 may choose not to recommend any furnishing plan to user device 220. In some embodiments, interior design device 200 may start method 300 all over again to generate a new furnishing plan. For example, in method 300, interior design device 200 may select different candidate furnishing items 216 as before, or generate a placement item set to include different furnishing items as before.

In an exemplary experiment performed on 1000 rooms, 84.4% initial furnishing plans generated by the disclosed systems and methods meet placement criteria and can be recommended to users directly. Among the remaining 15.6% that requires adjustment to the initial furnishing plans, 12.2% can be successfully adjusted to meet the placement criteria, and only 3.4% fails. The experiment results thus show the reliability and robustness of the disclosed systems and methods to automatically generating furnishing plans.

The disclosed systems and methods improve the existing computer-aided furnishing solutions in several aspects. First, the generated furnishing plan can guarantee basic functionality of the furnished room. For example, a bedroom will have at least a bed for the occupant to sleep on and a bathroom will have at least a vanity for washing and grooming. Further, by selecting furnishing items to be included in the furnishing plan based on the resident profile, the generated furnishing plan can account for the occupant's preferences. Also, by using the area occupation ratio as a condition when selecting the furnishing items, the generated furnishing plan can result in a reasonable furniture distribution density and traffic flow in the room. In addition, the disclosed systems and methods are designed to include as many furnishing items as possible in the placement item set, as long as the placement has an area occupation ratio less than the threshold. Therefore, the generated furnishing plan can most effectively use the space available in the room.

Another aspect of the disclosure is directed to a non-transitory computer-readable medium storing instruction which, when executed, cause one or more processors to perform the methods, as discussed above. The computer-readable medium may include volatile or non-volatile, magnetic, semiconductor, tape, optical, removable, non-removable, or other types of computer-readable medium or computer-readable storage devices. For example, the computer-readable medium may be the storage device or the memory module having the computer instructions stored thereon, as disclosed. In some embodiments, the computer-readable medium may be a disc or a flash drive having the computer instructions stored thereon.

Although the embodiments are described using interior design of indoor spaces as examples, it is contemplated that the concepts could be readily expanded and adapted to design of outdoor spaces, such as the deck, the front/back yard, the garage, as well as the neighboring environment. A person of ordinary skill can adapt the disclosed systems and methods without undue experimentation for outdoor designs.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims and their equivalents.

1. A system for generating a furnishing plan for a room, comprising:
a communication interface configured to receive a floor plan of the room and a resident profile; and
at least one processor configured to:
determine a functionality of the room at least partially based on the resident profile;
obtain a set of candidate furnishing items for the room based on the functionality of the room;
sequentially add furnishing items selected from the set of candidate furnishing items to a placement item set, wherein the furnishing items added in the placement item set collectively meet a predetermined area occupation threshold associated with the floor plan; and
generate the furnishing plan based on the placement item set.

2. The system of claim 1, wherein each candidate furnishing item is associated with a priority at least partially based on the resident profile, wherein the furnishing items are selected from the set of candidate furnishing items and sequentially added to the placement item set according to their priorities.

3. The system of claim 1, wherein to sequentially add the furnishing items, the at least one processor is further configured to:
select a next furnishing item from the set of candidate furnishing items;
calculate a total area occupied by the next furnishing item along with existing furnishing items previously added in the placement item set; and
determine whether adding the next furnishing item meets the predetermined area occupation threshold based on the total occupied area and an effective area of the room determined based on the floor plan.

4. The system of claim 3, wherein when the next furnishing item does not meet the predetermined area occupation threshold, the at least one processor is further configured to:
select a substitute furnishing item of the next furnishing item, wherein the substitute furnishing item is of a same furniture type as the next furnishing item but occupies a smaller area than the next furnishing item;
calculate a total area occupied by the substitute furnishing item along with existing furnishing items previously added in the placement item set; and
determine whether adding the substitute furnishing item meets the predetermined area occupation threshold based on the total occupied area and the effective area of the room.

5. The system of claim 3, wherein to calculate the total area, the at least one processor is further configured to:
calculate an occupied area of the next furnishing item based on dimensions of the next furnishing item and allowances associated with the next furnishing item; and
add the occupied area of the next furnishing item with a total area of the existing furnishing items.

6. The system of claim 1, wherein the room is a part of a property, wherein to determine the functionality of the room based on the resident profile, the at least one processor is further configured to:
determine a required number of bedrooms based on the resident profile;
determine that the room is a bedroom when current number of bedrooms in the property does not meet the required number of bedrooms; and
determine that the room is a non-bedroom when the current number of bedrooms in the property meets the required number of bedrooms.

7. The system of claim 6, wherein when the room is determined to be a non-bedroom, the at least one processor is further configured to:
select the functionality of the room from a list of functionalities arranged in a predetermined order.

8. The system of claim 6, wherein the required number of bedrooms is determined based on the demography of residents indicated by the resident profile.

9. The system of claim 1, wherein to obtain a set of candidate furnishing items for the room, the at least one processor is further configured to:
determine an occupant of the room;
determine characteristics and preferences of the occupant based on the resident profile; and
assign priorities to the set of candidate furnishing items based on the characteristics and preferences of the occupant.

10. The system of claim 1, wherein the at least one processor is further configured to:
determine that the furnishing plan does not meet one or more placement criteria;
adjust at least one furnishing item in the placement item set until the furnishing plan meets the one or more placement criteria; and
generate a new furnishing plan based on the adjusted placement item set.

11. The system of claim 10, wherein to adjust the at least one furnishing item in the placement item set, the at least one processor is further configured to:
traverse the furnishing items in the placement item set in a reverse order; and
replace at least one furnishing item with a respective substitute furnishing item or delete the furnishing item until the furnishing plan meets the one or more placement criteria.

12. The system of claim 10, where to determine that the furnishing plan does not meet one or more placement criteria, the at least one processor is further configured to:
calculate a matching score between the furnishing plan and the floor plan; and
compare the matching score with a predetermined threshold.

13. A computer-implemented method for generating a furnishing plan of a room, comprising:
receiving, by a communication interface, a floor plan of the room and a resident profile;
determining, by at least one processor, a functionality of the room based at least partially on the resident profile;
obtaining a set of candidate furnishing items for the room based on the functionality of the room;
sequentially adding, by the at least one processor, furnishing items selected from the set of candidate furnishing items to a placement item set, wherein the furnishing items added in the placement item set collectively meet a predetermined area occupation threshold associated with the floor plan; and
generating, by the at least one processor, the furnishing plan based on the placement item set.

14. The computer-implemented method of claim 13, wherein each candidate furnishing item is associated with a priority at least partially based on the resident profile, wherein sequentially adding the furnishing items further includes sequentially selecting the furnishing items from the set of candidate furnishing items according to their priorities.

15. The computer-implemented method of claim 13, wherein sequentially adding the furnishing items further comprises:
selecting a next furnishing item from the set of candidate furnishing items;
calculating a total area occupied by the next furnishing item along with existing furnishing items previously added in the placement item set; and
determining whether adding the next furnishing item meets the predetermined area occupation threshold based on the total occupied area and an effective area of the room determined based on the floor plan.

16. The computer-implemented method of claim 15, wherein when the next furnishing item does not meet the predetermined area occupation threshold, the method further comprises:
selecting a substitute furnishing item of the next furnishing item, wherein the alternative furnishing item is of a same furniture type as the next furnishing item but occupies a smaller area than the next furnishing item;
calculating a total area occupied by the substitute furnishing item along with existing furnishing items previously added in the placement item set; and
determining whether adding the substitute furnishing item meets the predetermined area occupation threshold based on the total occupied area and the effective area of the room.

17. The computer-implemented method of claim 13, wherein the room is a part of a property, wherein determining the functionality of the room based on the resident profile further comprises:
determining a required number of bedrooms based on the resident profile;
determining that the room is a bedroom when current number of bedrooms in the property does not meet the required number of bedrooms; and
determine the functionality of the room from a list of functionalities arranged in a predetermined order, when the current number of bedrooms in the property meets the required number of bedrooms.

18. The computer-implemented method of claim 13, further comprising:
determining that the furnishing plan does not meet placement criteria;
adjusting at least one furnishing item in the placement item set until the furnishing plan meets the placement criteria; and
generating a new furnishing plan based on the adjusted placement item set.

19. The computer-implemented method of claim 18, wherein adjusting the at least one furnishing item in the placement item set, the at least one processor is further configured to:
traverse the furnishing items in the placement item set in a reverse order of priority; and
replacing at least one furnishing item with a respective substitute furnishing item or deleting the furnishing item until the furnishing plan meets the placement criteria.

20. A non-transitory computer-readable medium having stored thereon computer instructions, when executed by at least one processor, perform a method generating a furnishing plan of a room, comprising:
receiving a floor plan of the room and a resident profile;
determining a functionality of the room based at least partially on the resident profile;
obtaining a set of candidate furnishing items for the room based on the functionality of the room;
sequentially adding furnishing items selected from the set of candidate furnishing items to a placement item set, wherein the furnishing items added in the placement item set collectively meet a predetermined area occupation threshold associated with the floor plan; and
generating, the furnishing plan based on the placement item set.
